(19) United States
(12) Patent Application Publication
(10) Pub. No.: US 2025/0211203 A1
(43) Pub. Date: Jun. 26, 2025

(54) FUNDAMENTAL TONE MITIGATION FOR SECOND OVERTONE BULK ACOUSTIC WAVE RESONATOR

(71) Applicant: SKYWORKS SOLUTIONS, INC., Irvine, CA (US)

(72) Inventors: Ahmed E. Hassanien, Savoy, IL (US); Scott J. Smith, Hollis, NH (US)

(21) Appl. No.: 18/983,836

(22) Filed: Dec. 17, 2024

Related U.S. Application Data
(60) Provisional application No. 63/614,087, filed on Dec. 22, 2023.

(51) Int. Cl. H03H 9/56; H03H 3/04

(52) U.S. Cl. CPC H03H 9/568; H03H 3/04; H03H 9/562; H03H 9/564; H03H 2003/0428; H03H 2003/0435

(57) ABSTRACT

Aspects and embodiments disclosed herein include a radio frequency filter comprising a plurality of series bulk acoustic wave resonators and a plurality of shunt bulk acoustic wave resonators, the plurality of series bulk acoustic wave resonators and the plurality of shunt bulk acoustic wave resonators configured and arranged to generate acoustic waves at both fundamental tones and second overtones and to suppress signals associated with the acoustic waves at the fundamental tones, a passband of the radio frequency filter with a lowest insertion loss defined by the acoustic waves generated at the second overtones of the plurality of series bulk acoustic wave resonators and the plurality of shunt bulk acoustic wave resonators.

### CROSS-REFERENCE TO RELATED APPLICATIONS

This application claims priority under 35 U.S.C. § 119 (e) to U.S. Provisional Patent Application Ser. No. 63/614,087, titled “FUNDAMENTAL TONE MITIGATION FOR SECOND OVERTONE BULK ACOUSTIC WAVE RESONATOR,” filed Dec. 22, 2023, the entire content of which is incorporated herein by reference.

### TECHNICAL FIELD

Embodiments of this disclosure relate to bulk acoustic wave resonators and to acoustic wave filters including same in which the bulk acoustic wave resonators utilize the second overtone of vibration of their piezoelectric material films to generate the main acoustic waves used by the resonators and in which the fundamental tone is suppressed.

### DESCRIPTION OF RELATED TECHNOLOGY

Acoustic wave filters can filter radio frequency signals. An acoustic wave filter can include a plurality of resonators arranged to filter a radio frequency signal. The resonators can be arranged as a ladder circuit. Example acoustic wave filters include surface acoustic wave (SAW) filters, bulk acoustic wave (BAW) filters, and Lamb wave resonator filters. A film bulk acoustic resonator filter is an example of a BAW filter. A solidly mounted resonator (SMR) filter is another example of a BAW filter.

Acoustic wave filters can be implemented in radio frequency electronic systems. For instance, filters in a radio frequency front end of a mobile phone can include acoustic wave filters. Two acoustic wave filters can be arranged as a duplexer.

### SUMMARY

In accordance with one aspect, there is provided a radio frequency filter. The radio frequency filter comprises a plurality of series bulk acoustic wave resonators, and a plurality of shunt bulk acoustic wave resonators, the plurality of series bulk acoustic wave resonators and the plurality of shunt bulk acoustic wave resonators configured and arranged to generate acoustic waves at both fundamental tones and second overtones and to suppress signals associated with the acoustic waves at the fundamental tones, a passband of the radio frequency filter with a lowest insertion loss defined by the acoustic waves generated at the second overtones of the plurality of series bulk acoustic wave resonators and the plurality of shunt bulk acoustic wave resonators.

In some embodiments, resonant frequencies of the fundamental tone of the plurality of series bulk acoustic wave resonators are aligned in frequency with resonant frequencies of the fundamental tone of the plurality of shunt bulk acoustic wave resonators.

In some embodiments, resonant frequencies of the second overtones of the plurality of series bulk acoustic wave resonators are aligned in frequency with antiresonant frequencies of the second overtones of the plurality of shunt bulk acoustic wave resonators.

In some embodiments, the plurality of series bulk acoustic wave resonators and the plurality of shunt bulk acoustic wave resonators each include piezoelectric material layers and dielectric layers disposed on top of the piezoelectric material layers and having thicknesses sufficient to cause the second overtones to be excited.

In some embodiments, the plurality of series bulk acoustic wave resonators and the plurality of shunt bulk acoustic wave resonators each include piezoelectric material layers and dielectric layers disposed on top of the piezoelectric material layers and having thicknesses sufficient to cause the second overtones to be excited with amplitudes at least as great as amplitudes of the fundamental tones.

In some embodiments, the plurality of series bulk acoustic wave resonators and the plurality of shunt bulk acoustic wave resonators are film bulk acoustic wave resonators.

In some embodiments, the plurality of series bulk acoustic wave resonators and the plurality of shunt bulk acoustic wave resonators are solidly mounted resonators.

In some embodiments, the radio frequency filter is configured as a ladder filter.

In some embodiments, the radio frequency filter is included in a radio frequency module.

In some embodiments, the radio frequency module is included in a radio frequency device.

In accordance with another aspect, there is provided a method of forming a radio frequency ladder filter having a passband. The method comprises forming a ladder filter including a plurality of series resonators coupled between an input and an output and a plurality of shunt resonators electrically connected between nodes between adjacent ones of the plurality of series resonators and ground, and selecting thickness of a piezoelectric material layer, top electrode, and bottom electrode of series resonators of the filter to center a second overtone resonant frequency of each of the plurality of series resonators at an upper end of the passband.

In some embodiments, the method further comprises determining a second overtone resonance frequency of shunt resonators of the filter to give a desired passband width for the filter.

In some embodiments, the method further comprises calculating a spacing between the second overtone resonance frequencies of the series and shunt resonators.

In some embodiments, the method further comprises calculating values for ΔT_{MTE} and ΔT_{SV} that would achieve the spacing between the second overtone resonance frequencies of the series and shunt resonators and a difference in resonance frequencies of the series and shunt resonators at fundamental tones of the series and shunt resonators of about 0 MHz.

In some embodiments, forming the ladder filter includes forming the series and shunt resonators with the selected thicknesses of the piezoelectric material layer, top electrode, and bottom electrode and the calculated values for ΔT_{MTE} and ΔT_{SV}.

In some embodiments, the values for ΔT_{MTE} and ΔT_{SV} are calculated from the formula

$$Δ {f}_{s} = \frac{Δ {f}_{s}}{Δ {T}_{MTE}} \times Δ {T}_{MTE} + \frac{Δ {f}_{s}}{Δ {T}_{SV}} \times Δ {T}_{SV} .$$

In some embodiments, the series and shunt resonators are formed as film bulk acoustic wave resonators.

In some embodiments, the series and shunt resonators are formed as solidly mounted resonators.

In some embodiments, the method further comprises incorporating the radio frequency ladder filter into a radio frequency module.

In some embodiments, the method further comprises incorporating the radio frequency module into a radio frequency device.

### BRIEF DESCRIPTION OF THE DRAWINGS

Embodiments of this disclosure will now be described, by way of non-limiting example, with reference to the accompanying drawings.

FIG. 1 is a cross-sectional view of an example of film bulk acoustic wave resonator;

FIG. 2 is a cross-sectional view of an example of a surface mounted resonator;

FIG. 3 illustrates an example of a stack of material layers disposed above and below a piezoelectric material layer of a BAW resonator;

FIG. 4A illustrates frequency response of an example of a film bulk acoustic wave resonator in which both a fundamental tone and a second overtone are excited;

FIG. 4B is an enlarged view of the frequency response in the region of the fundamental tone of FIG. 4A;

FIG. 4C is an enlarged view of the frequency response in the region of the second overtone of FIG. 4A;

FIG. 5 illustrates insertion loss of a ladder filter formed of film bulk acoustic wave resonators in which both fundamental tones and second overtones are excited and in which effects of the fundamental tones are not suppressed;

FIG. 6 illustrates an example of a ladder filter;

FIG. 7A illustrates the concept of aligning resonance frequencies of the fundamental tones of series and shunt resonators in a ladder filter to cancel the effect of the fundamental tone on frequency response of the filter;

FIG. 7B illustrates the concept of aligning the resonance frequency of the second overtone of series resonators in a ladder filter with the antiresonance frequency of the second overtone of shunt resonators in a ladder filter to form passband around the resonance frequency of the second overtone of the resonators;

FIG. 7C illustrates a passband formed around the resonance frequency of the second overtone of the resonators in a ladder filter in which the resonance and antiresonance frequencies of the resonators are aligned as illustrated in FIG. 7B;

FIG. 7D illustrates how frequency response at the fundamental overtone of resonators in a ladder filter may be suppressed by aligning the resonance frequencies of the series and shunt resonators as illustrated in FIG. 7A;

FIG. 8 illustrates an embodiment of an electronics module;

FIG. 9 illustrates an example of a front-end module which may be used in an electronic device; and

FIG. 10 illustrates an example of an electronic device.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Film bulk acoustic wave resonators are a form of bulk acoustic wave resonator that generally includes a film of piezoelectric material sandwiched between a top and a bottom electrode and suspended over a cavity that allows for the film of piezoelectric material to vibrate. A signal applied across the top and bottom electrodes causes an acoustic wave to be generated in and travel through the film of piezoelectric material. A film bulk acoustic wave resonator exhibits a frequency response to applied signals with a resonance peak determined by a thickness of the film of piezoelectric material. Ideally, the only acoustic wave that would be generated in a film bulk acoustic wave resonator is a main acoustic wave that would travel through the film of piezoelectric material in a direction perpendicular to layers of conducting material forming the top and bottom electrodes. The piezoelectric material of a film bulk acoustic wave resonator, however, typically has a non-zero Poisson's ratio. Compression and relaxation of the piezoelectric material associated with passage of the main acoustic wave may thus cause compression and relaxation of the piezoelectric material in a direction perpendicular to the direction of propagation of the main acoustic wave. The compression and relaxation of the piezoelectric material in the direction perpendicular to the direction of propagation of the main acoustic wave may generate transverse acoustic waves that travel perpendicular to the main acoustic wave (parallel to the surfaces of the electrode films) through the piezoelectric material. The transverse acoustic waves may be reflected back into an area in which the main acoustic wave propagates and may induce spurious acoustic waves travelling in the same direction as the main acoustic wave. These spurious acoustic waves may degrade the frequency response of the film bulk acoustic wave resonator from what is expected or from what is intended and are generally considered undesirable.

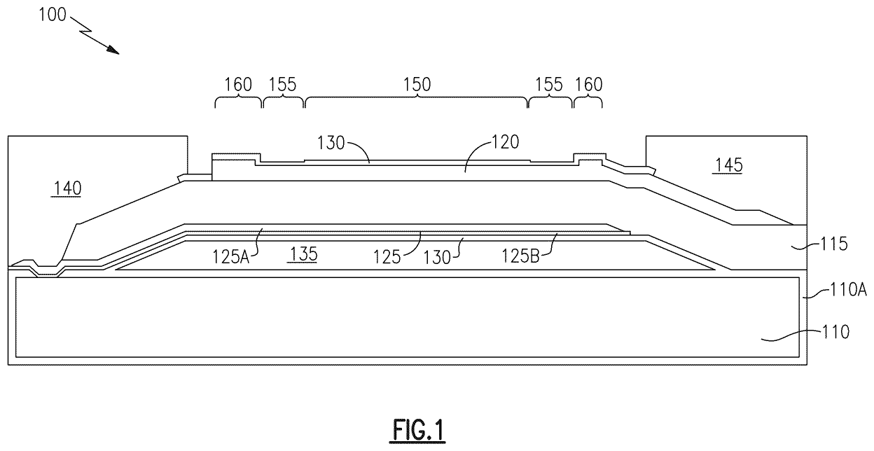

FIG. 1 is cross-sectional view of an example of a film bulk acoustic wave resonator, indicated generally at 100. The film bulk acoustic wave resonator 100 is disposed on a substrate 110, for example, a silicon substrate that may include a dielectric surface layer 110A of, for example, silicon dioxide. The film bulk acoustic wave resonator 100 includes a layer or film of piezoelectric material 115, for example, aluminum nitride (AlN) or scandium-doped aluminum nitride (AlₓSc₁₋ₓN, referred to herein without subscripts as AlScN). A top electrode 120 (often abbreviated MTE) is disposed on top of a portion of the layer or film of piezoelectric material 115 and a bottom electrode 125 (often abbreviated MBE) is disposed on the bottom of a portion of the layer or film of piezoelectric material 115. The top electrode 120 may be formed of, for example, ruthenium (Ru). The bottom electrode 125 may include a layer 125A of Ru disposed in contact with the bottom of the portion of the layer or film of piezoelectric material 115 and a layer 125B of titanium (Ti) disposed on a lower side of the layer 125A of Ru opposite a side of the layer 125A of Ru in contact with the bottom of the portion of the layer or film of piezoelectric material 115. Each of the top electrode 120 and the bottom electrode 125 may be covered with a layer of dielectric material 130, for example, silicon dioxide. A cavity 135 is defined beneath the layer of dielectric material 130 covering the bottom electrode 125 and the surface layer 110A of the substrate 110. A bottom electrical contact 140 formed of, for example, copper may make electrical connection with the bottom electrode 125 and a top electrical contact 145 formed of, for example, copper may make electrical connection with the top electrode 120.

The film bulk acoustic wave resonator 100 may include a central region 150 including a main active domain in the layer or film of piezoelectric material 115 in which a main acoustic wave is excited during operation. The central region may have a width of, for example, between about 20 μm and about 100 μm. A recessed frame region or regions 155 may bound and define the lateral extent of the central region 150. The recessed frame regions may have a width of, for example, about 1 μm. The recessed frame region(s) 155 may be defined by areas that have a thinner layer of dielectric material 130 on top of the top electrode 120 than in the central region 150. The dielectric material layer 130 in the recessed frame region(s) 155 may be from about 10 nm to about 100 nm thinner than the dielectric material layer 130 in the central region 150. The difference in thickness of the dielectric material in the recessed frame region(s) 155 vs. in the central region 150 may cause the resonant frequency of the device in the recessed frame region(s) 155 to be between about 5 MHz to about 50 MHz higher than the resonant frequency of the device in the central region 150. In some embodiments, the thickness of the dielectric material layer 130 in the central region 150 may be about 200 nm to about 300 nm and the thickness of the dielectric material layer 130 in the recessed frame region(s) 155 may be about 100 nm. The dielectric film 300 in the recessed frame region(s) 155 is typically etched during manufacturing to achieve a desired difference in acoustic velocity between the central region 150 and the recessed frame region(s) 155. Accordingly, the dielectric film 300 initially deposited in both the central region 150 and recessed frame region(s) 155 is deposited with a sufficient thickness that allows for etching of sufficient dielectric film 300 in the recessed frame region(s) 155 to achieve a desired difference in thickness of the dielectric film 300 in the central region 150 and recessed frame region(s) 155 to achieve a desired acoustic velocity difference between these regions.

A raised frame region or regions 160 may be defined on an opposite side of the recessed frame region(s) 155 from the central region 150 and may directly abut the outside edge(s) of the recessed frame region(s) 155. The raised frame regions may have widths of, for example, about 1 μm. The raised frame region(s) 160 may be defined by areas where the top electrode 120 is thicker than in the central region 150 and in the recessed frame region(s) 155. The top electrode 120 may have the same thickness in the central region 150 and in the recessed frame region(s) 155 but a greater thickness in the raised frame region(s) 160. The top electrode 120 may be between about 50 nm and about 500 nm thicker in the raised frame region(s) 160 than in the central region 150 and/or in the recessed frame region(s) 155. In some embodiments the thickness of the top electrode in the central region may be between 50 and 500 nm.

The recessed frame region(s) 155 and the raised frame region(s) 160 may contribute to dissipation or scattering of transverse acoustic waves generated in the film bulk acoustic wave resonator 100 during operation and/or may reflect transverse waves propagating outside of the recessed frame region(s) 155 and the raised frame region(s) 160 and prevent these transverse acoustic waves from entering the central region and inducing spurious signals in the main active domain region of the film bulk acoustic wave resonator. Without being bound to a particular theory, it is believed that due to the thinner layer of dielectric material 130 on top of the top electrode 120 in the recessed frame region(s) 155, the recessed frame region(s) 155 may exhibit a higher velocity of propagation of acoustic waves than the central region 150. Conversely, due to the increased thickness and mass of the top electrode 120 in the raised frame region(s) 160, the raised frame regions(s) 160 may exhibit a lower velocity of propagation of acoustic waves than the central region 150 and a lower velocity of propagation of acoustic waves than the recessed frame region(s) 155. The discontinuity in acoustic wave velocity between the recessed frame region(s) 155 and the raised frame region(s) 160 creates a barrier that scatters, suppresses, and/or reflects transverse acoustic waves.

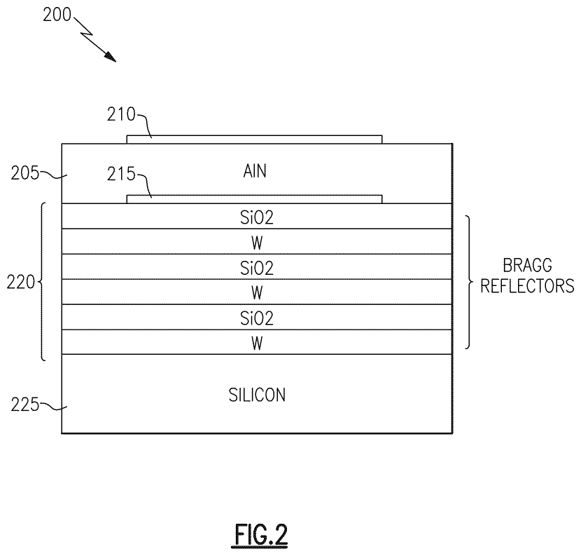

Another form of BAW resonator is a surface mounted resonator (SMR). An example of an SMR is illustrated generally at 200 in FIG. 2. As illustrated, the SMR 200 includes a piezoelectric material layer 205, an upper electrode 210 (MTE) on the piezoelectric material layer 205, and a lower electrode 215 (MBE) on a lower surface of the piezoelectric material layer 205. The piezoelectric material layer 205 can be an AlN or AlScN layer. In other instances, the piezoelectric material layer 205 can be formed of any other suitable piezoelectric material. The lower electrode 215 can be grounded in certain instances. In some other instances, the lower electrode 215 can be floating. Bragg reflectors 220 are disposed between the lower electrode 215 and a semiconductor substrate 225. The semiconductor substrate 225 can be a silicon substrate. Any suitable Bragg reflectors can be implemented. For example, the Bragg reflectors can be SiO₂/W.

It should be appreciated that the BAW resonators and piezoelectric material layers illustrated in the figures are illustrated in a highly simplified form. The relative dimensions of the different features are not shown to scale. Further, typical BAW resonators may include additional features or layers not illustrated.

As noted above, the operating frequency of a BAW resonator is dependent on the thickness of the piezoelectric material film within the BAW resonator; generally, the thinner the piezoelectric material film the higher the operating frequency. The market is continuing to demand wireless devices operating at higher and higher frequencies. Piezoelectric material layers in BAW resonators, however, can only be made so thin before manufacturing repeatability and operational reliability begin to suffer. In the past most BAW resonators utilized an acoustic wave that was generated at the fundamental tone or first harmonic frequency of vibration of their piezoelectric material layers. It has been discovered that it is possible to reliably cause the piezoelectric material film of a BAW resonator to vibrate at not just its fundamental tone or first harmonic but also at its second overtone or second harmonic. The second overtone or second harmonic is typically about twice the frequency of the fundamental tone or first harmonic, subject to some reduction in frequency due to the mass of the electrodes and other material layers deposited on or below the piezoelectric material layer of the resonator. Utilizing the second harmonic rather than the first harmonic of BAW resonators in a RF filter may provide for the filter to operate at higher frequencies without having to reduce the thickness of the piezoelectric material films of the resonators to thicknesses that might cause manufacturing repeatability or operational reliability issues. The generation of the fundamental tone in BAW resonators utilized to form an RF filter along with the second harmonic, however, may result in spurious signals in the filter that degrade performance when utilizing the second harmonic as the main acoustic wave of the resonators, for example, by undesirably allowing signals to pass at frequencies around the frequency of the fundamental tone of the resonators rather than only around the frequency of the second overtone. Accordingly, methods to both induce generation of the second harmonic or second overtone in BAW resonators in a RF filter while suppressing the fundamental tone are desired.

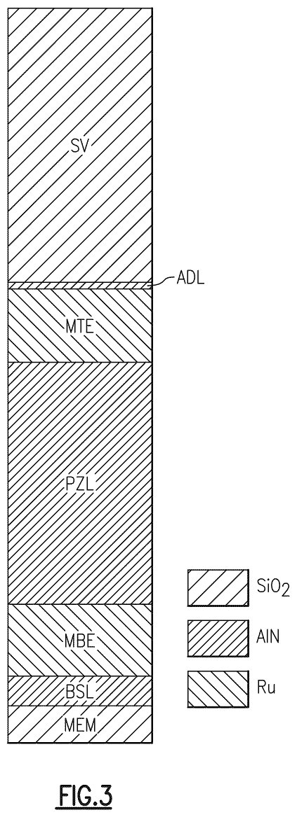

FIG. 3 is a more detailed illustration of the layers above and below the piezoelectric material layer of an example of a BAW resonator than is provided in FIG. 1 or 2. As illustrated in FIG. 3, the piezoelectric material layer (PZL in FIG. 3) is sandwiched between a lower electrode (MBE) and an upper electrode (MTE). Below the MBE is a seed layer (BSL) upon which the MBE is grown during manufacturing. A lower SiO₂ layer that may correspond to the lower dielectric material layer 130 in the film bulk acoustic wave resonator of FIG. 1 may be disposed below the BSL layer and may be used as an etch stop layer during manufacturing. Disposed on top of the MTE is an adhesion layer (ADL) formed of, for example, Ti, and disposed on top of the ADL layer is a passivation/trimming/temperature compensation layer (SV) which may correspond to the upper dielectric material layer 130 in the film bulk acoustic wave resonator of FIG. 1.

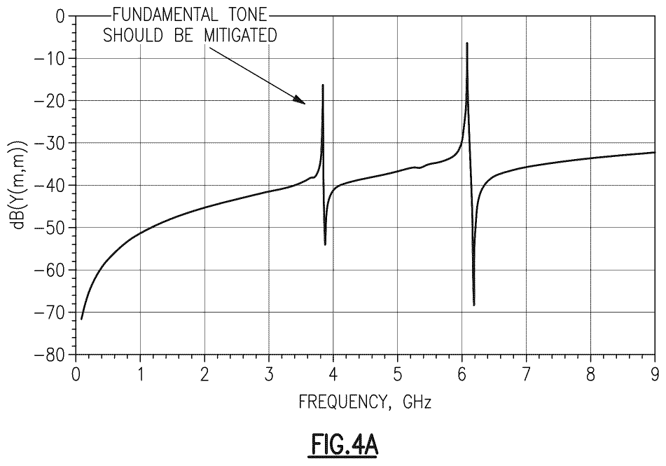

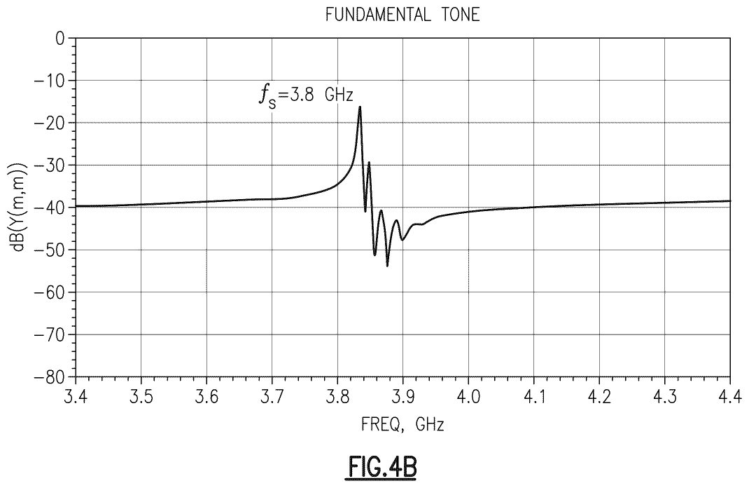

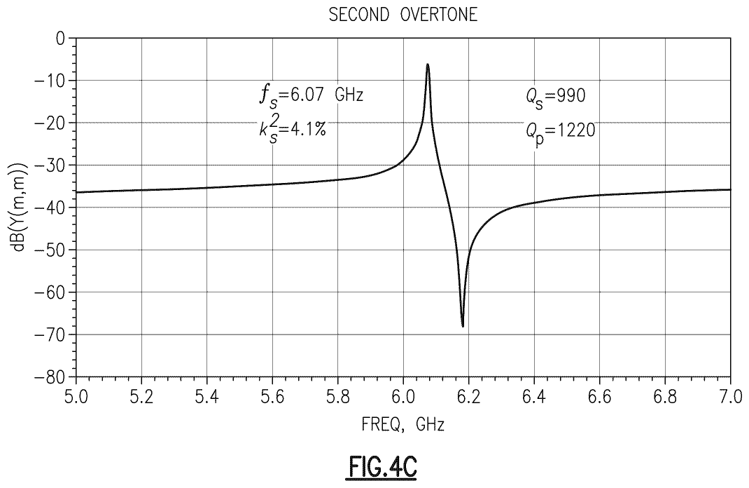

In film bulk acoustic wave resonators which utilize the fundamental vibrational mode of their piezoelectric material film as the main acoustic wave, the SV layer may be about 100 nm thick for resonators with series resonance frequencies fₛ of about 4 GHz. The MBE and MTE layers may also be about 100 nm thick for resonators operating at about this frequency. It has been discovered that increasing the thickness of the SV layer to, for example, about 400 nm may cause the piezoelectric material film of a BAW resonator to vibrate not just at its fundamental tone, but also at its second overtone. FIG. 4A illustrates the frequency response of a film bulk acoustic wave resonator configured in this manner, which may be referred to herein as a Second Overtone BAW (SOBAW). FIGS. 4B and 4C show details of the frequency response at the fundamental tone (fₛ=3.8 GHz) and the second overtone (fₛ=6.07 GHZ), respectively.

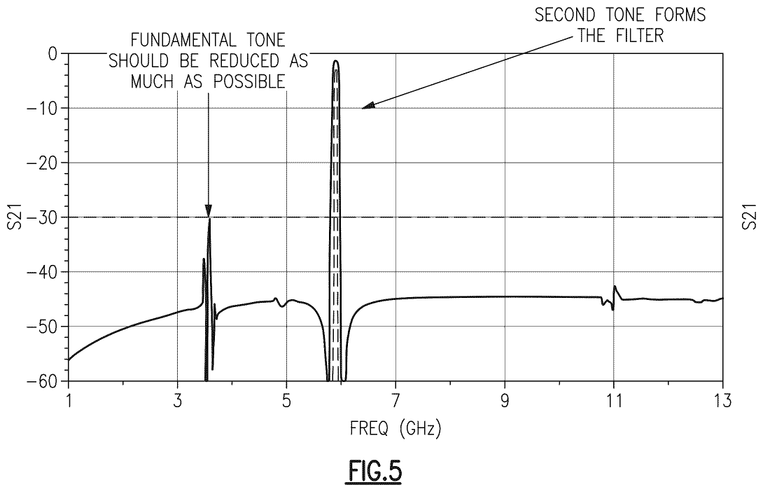

FIG. 5 illustrates insertion loss of a ladder filter formed from BAW resonators having frequency responses as illustrated in FIGS. 4A-4C. The filter exhibits a desired primary passband at about 6 GHz that is formed by the acoustic waves at the second overtone vibrations of the resonators of the filter, but also a second, undesired passband at about 3.8 GHz formed by the first overtone vibrations of the resonators of the filter.

It has been discovered that both the frequencies at which the first and second overtone vibrations of the piezoelectric material film of a SOBAW are sensitive to the thickness of the MTE and to the thickness of the SV layer. The change in resonant frequency of the second overtone may be more sensitive to changes in thickness of the MTE than the change in resonant frequency of the first overtone by more than an order of magnitude. The change in resonant frequency of the first overtone may be more sensitive to changes in thickness of the SV layer than the change in resonant frequency of the second overtone. In one example, a film bulk acoustic wave resonator having a frequency response as illustrated in FIGS. 4A-4C with a MTE thickness of 100 nm was found to exhibit the following sensitivities of frequencies at which the resonant frequencies of the fundamental tone and second overtone occurred (Δfₛ) to changes in the thicknesses of the MTE (ΔT_{MTE}) and SV (ΔT_{SV}) layers:

$$Second Overtone : \frac{Δ {f}_{s}}{Δ {T}_{MTE}} = - 11.1 \frac{MHz}{nm}$$

$$Fundamental Tone : \frac{Δ {f}_{s}}{Δ {T}_{MTE}} = - 0.85 \frac{MHz}{nm}$$

This means the sensitivity of fundamental tone to change in thickness of MTE is more than 10× smaller than that of the second overtone.

For changes in thickness of the SV layer:

$$Second Overtone : Δ {f}_{s} / Δ {T}_{SV} = - 3 \text{.83} MHz / nm$$

$$Fundamental Tone : Δ {f}_{s} / Δ {T}_{SV} = - 6 \text{.47} MHz / nm$$

It is to be appreciated that these sensitivity values may differ depending upon the configuration and operational frequency of a particular film bulk acoustic wave resonator. Sensitivities of resonant frequencies of fundamental tones and second overtones in SMRs are expected to exhibit similar effects as in film bulk acoustic wave resonators, but the magnitude of the sensitivities would likely be different.

The shift in the resonance frequency for either the fundamental tone or the second overtone of a BAW resonator with changes in MTE and SV layer thicknesses may be calculated in accordance with the formula:

$$Δ {f}_{s} = \frac{Δ {f}_{s}}{Δ {T}_{MTE}} \times Δ {T}_{MTE} + \frac{Δ {f}_{s}}{Δ {T}_{SV}} \times Δ {T}_{SV}$$

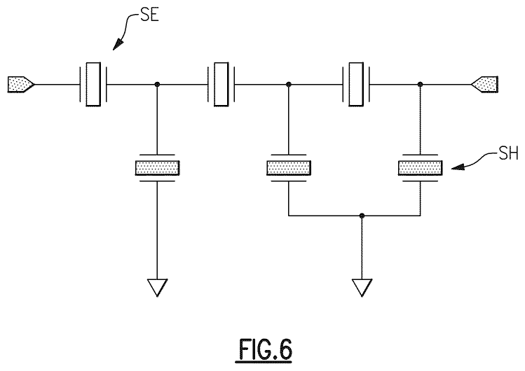

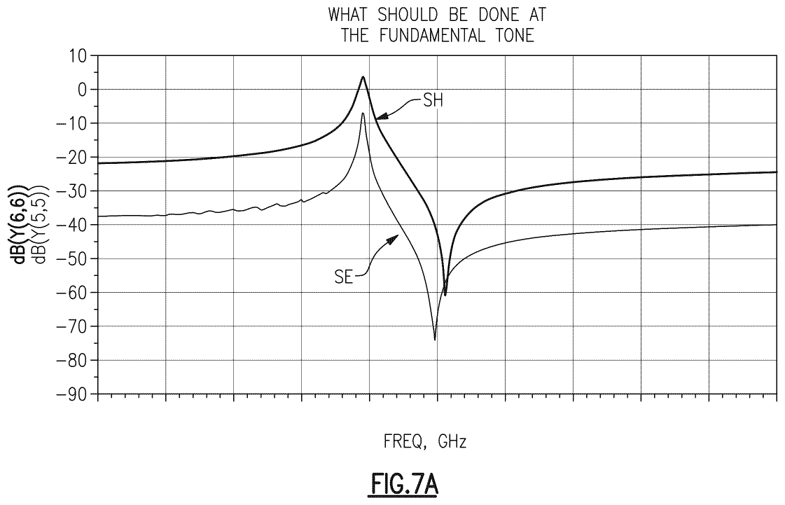

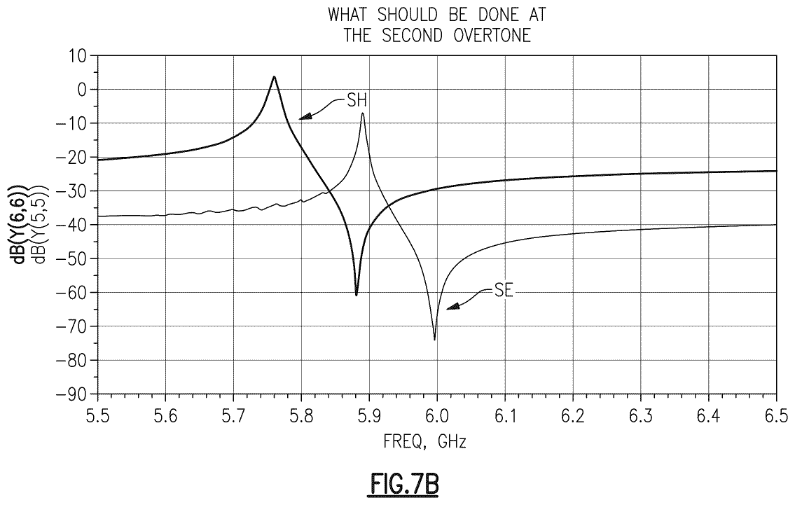

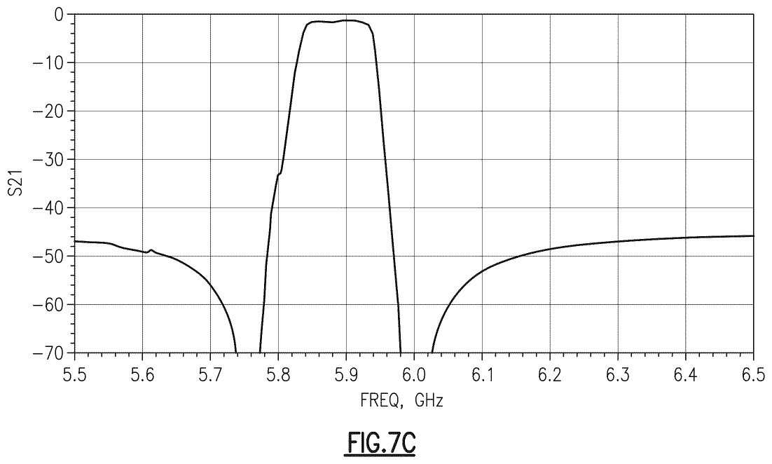

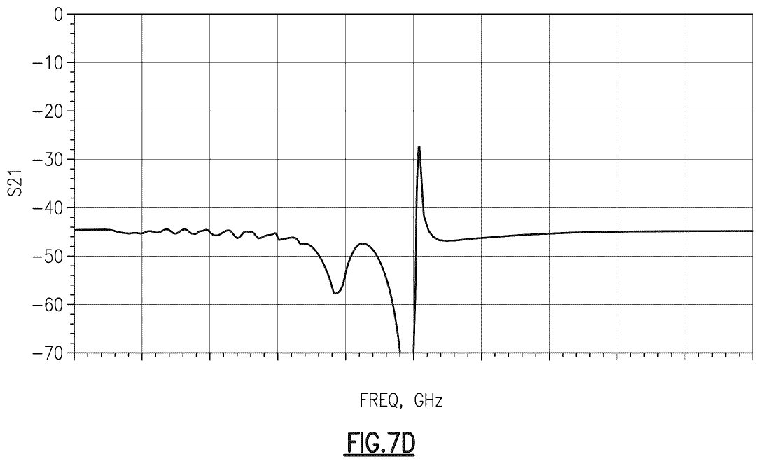

One may utilize these effects to align the location of the resonant frequency of the first overtone of the shunt resonators in a BAW ladder filter, for example, as illustrated in FIG. 6 (where SE indicates series resonators and SH indicates shunt resonators) with the location of the resonant frequency of the first overtone of the series resonators in the BAW ladder filter (See FIG. 7A) to cause the effects of the first overtones to cancel out, leaving only the second overtones of the resonators capable of making any significant contribution to the shape and location of the passband of the filter. This may be done by aligning the resonance frequencies of the series resonators with the anti-resonance frequencies of the shunt resonators (see FIG. 7B) as in a typical ladder filter either by appropriate selection of different piezoelectric material layer thicknesses and/or selection of different SV layer thicknesses and/or MTE thicknesses in the shunt and series resonators. The resonance frequencies of the second overtones in the series and shunt resonators may be selected by selection of the thicknesses of their respective MTEs or SV layers, although changes in the SV layer thicknesses would cause the resonance frequencies of the fundamental tones to change more than the resonance frequencies of the second overtones, so changes in SV layer thickness should be compensated for by changes in MTE thicknesses. This may cause the filter to exhibit a passband as shown in FIG. 7C with spurious signals due to the presence of the first overtones in the series and shunt resonators reduced to levels as shown in FIG. 7D.

One may define Δfₛ^{fund}=fₛ^{SH}−fₛ^{SE}≈0 to get better rejection of the first overtone. For ladder filters exhibiting a difference in resonance frequencies of the series and shunt resonators at the second overtone of about 130 MHz as illustrated in FIG. 7B, in accordance with the equations above, a change in MTE thickness from 100 nm to 113 nm would cause the resonance frequencies of the fundamental tones of the series and shunt resonators in a BAW ladder filter to align to provide for spurious signals associated with the fundamental tone to be substantially eliminated.

Design of a ladder filter to operate utilizing the second overtone of series and shunt resonators while suppressing effects of the first overtone may include selecting the thicknesses of the piezoelectric material layer, MTE, and MBE stack to center the second overtone of the series resonators at the frequency at the upper end of the passband of interest (for example, 6 GHZ). One would determine the second overtone resonance frequency of the shunt resonators to give the desired passband (for example, a resonance frequency of 5.87 GHz). One would calculate the spacing between resonance frequencies of the series and shunt resonators at the second overtone (for example, 130 MHz). One would then calculate values for ΔT_{MTE} and ΔT_{SV} that would achieve the desired spacing between resonance frequencies of the series and shunt resonators at the second overtone and a 0 MHz or about 0 MHz difference in resonance frequencies of the series and shunt resonators at their fundamental tones. This can be done using the equation

$$Δ {f}_{s} = \frac{Δ {f}_{s}}{Δ {T}_{MTE}} \times Δ {T}_{MTE} + \frac{Δ {f}_{s}}{Δ {T}_{SV}} \times Δ {T}_{SV}$$

at both the second overtone and at the fundamental tone, which would involve solving for a pair of simultaneous linear equations.

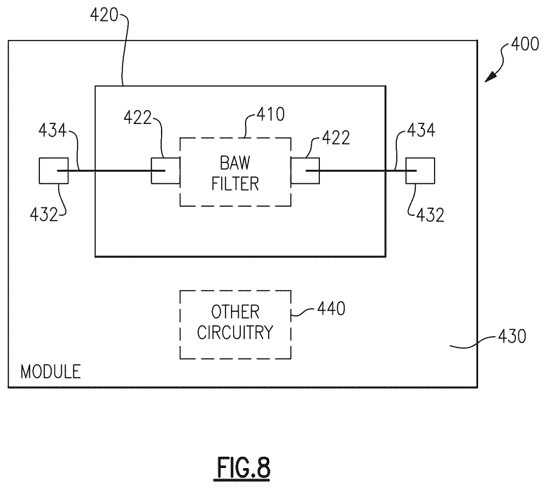

The acoustic wave devices discussed herein can be implemented in a variety of packaged modules. Some example packaged modules will now be discussed in which any suitable principles and advantages of the packaged acoustic wave devices discussed herein can be implemented. FIGS. 8, 9, and 10 are schematic block diagrams of illustrative packaged modules and devices according to certain embodiments.

As discussed above, embodiments of the disclosed BAW resonators can be configured as or used in filters, for example. In turn, a BAW filter using one or more BAW elements may be incorporated into and packaged as a module that may ultimately be used in an electronic device, such as a wireless communications device, for example. FIG. 8 is a block diagram illustrating one example of a module 400 including a BAW filter 410. The BAW filter 410 may be implemented on one or more die(s) 420 including one or more connection pads 422. For example, the BAW filter 410 may include a connection pad 422 that corresponds to an input contact for the BAW filter and another connection pad 422 that corresponds to an output contact for the BAW filter. The packaged module 400 includes a packaging substrate 430 that is configured to receive a plurality of components, including the die 420. A plurality of connection pads 432 can be disposed on the packaging substrate 430, and the various connection pads 422 of the BAW filter die 420 can be connected to the connection pads 432 on the packaging substrate 430 via electrical connectors 434, which can be solder bumps or wirebonds, for example, to allow for passing of various signals to and from the BAW filter 410. The module 400 may optionally further include other circuitry die 440, such as, for example, one or more additional filter(s), amplifiers, pre-filters, modulators, demodulators, down converters, and the like, as would be known to one of skill in the art of semiconductor fabrication in view of the disclosure herein. In some embodiments, the module 400 can also include one or more packaging structures to, for example, provide protection and facilitate easier handling of the module 400. Such a packaging structure can include an overmold formed over the packaging substrate 430 and dimensioned to substantially encapsulate the various circuits and components thereon.

Various examples and embodiments of the BAW filter 410 can be used in a wide variety of electronic devices. For example, the BAW filter 410 can be used in an antenna duplexer, which itself can be incorporated into a variety of electronic devices, such as RF front-end modules and communication devices.

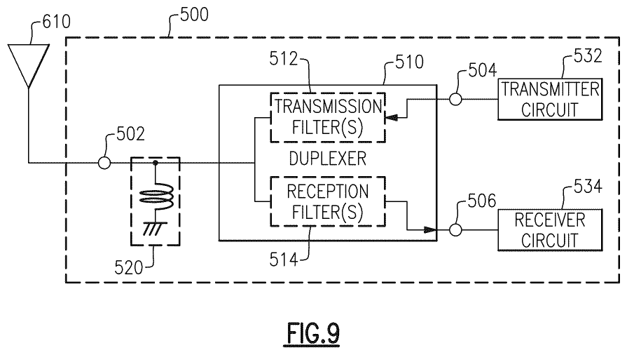

Referring to FIG. 9, there is illustrated a block diagram of one example of a front-end module 500, which may be used in an electronic device such as a wireless communications device (e.g., a mobile phone) for example. The front-end module 500 includes an antenna duplexer 510 having a common node 502, an input node 504, and an output node 506. An antenna 610 is connected to the common node 502.

The antenna duplexer 510 may include one or more transmission filters 512 connected between the input node 504 and the common node 502, and one or more reception filters 514 connected between the common node 502 and the output node 506. The passband(s) of the transmission filter(s) are different from the passband(s) of the reception filter(s). Examples of the BAW filter 410 can be used to form the transmission filter(s) 512 and/or the reception filter(s) 514. An inductor or other matching component 520 may be connected at the common node 502.

The front-end module 500 further includes a transmitter circuit 532 connected to the input node 504 of the duplexer 510 and a receiver circuit 534 connected to the output node 506 of the duplexer 510. The transmitter circuit 532 can generate signals for transmission via the antenna 610, and the receiver circuit 534 can receive and process signals received via the antenna 610. In some embodiments, the receiver and transmitter circuits are implemented as separate components, as shown in FIG. 9, however in other embodiments these components may be integrated into a common transceiver circuit or module. As will be appreciated by those skilled in the art, the front-end module 500 may include other components that are not illustrated in FIG. 9 including, but not limited to, switches, electromagnetic couplers, amplifiers, processors, and the like.

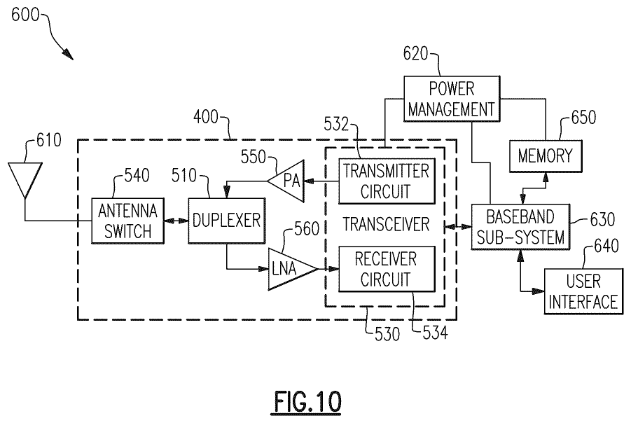

FIG. 10 is a block diagram of one example of a wireless device 600 including the antenna duplexer 510 shown in FIG. 9. The wireless device 600 can be a cellular phone, smart phone, tablet, modem, communication network or any other portable or non-portable device configured for voice or data communication. The wireless device 600 can receive and transmit signals from the antenna 610. The wireless device includes an embodiment of a front-end module 500 similar to that discussed above with reference to FIG. 9. The front-end module 500 includes the duplexer 510, as discussed above. In the example shown in FIG. 10 the front-end module 500 further includes an antenna switch 540, which can be configured to switch between different frequency bands or modes, such as transmit and receive modes, for example. In the example illustrated in FIG. 10, the antenna switch 540 is positioned between the duplexer 510 and the antenna 610; however, in other examples the duplexer 510 can be positioned between the antenna switch 540 and the antenna 610. In other examples the antenna switch 540 and the duplexer 510 can be integrated into a single component.

The front-end module 500 includes a transceiver 530 that is configured to generate signals for transmission or to process received signals. The transceiver 530 can include the transmitter circuit 532, which can be connected to the input node 504 of the duplexer 510, and the receiver circuit 534, which can be connected to the output node 506 of the duplexer 510, as shown in the example of FIG. 9.

Signals generated for transmission by the transmitter circuit 532 are received by a power amplifier (PA) module 550, which amplifies the generated signals from the transceiver 530. The power amplifier module 550 can include one or more power amplifiers. The power amplifier module 550 can be used to amplify a wide variety of RF or other frequency-band transmission signals. For example, the power amplifier module 550 can receive an enable signal that can be used to pulse the output of the power amplifier to aid in transmitting a wireless local area network (WLAN) signal or any other suitable pulsed signal. The power amplifier module 550 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 550 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 10, the front-end module 500 may further include a low noise amplifier module 560, which amplifies received signals from the antenna 610 and provides the amplified signals to the receiver circuit 534 of the transceiver 530.

The wireless device 600 of FIG. 10 further includes a power management sub-system 620 that is connected to the transceiver 530 and manages the power for the operation of the wireless device 600. The power management system 620 can also control the operation of a baseband sub-system 630 and various other components of the wireless device 600. The power management system 620 can include, or can be connected to, a battery (not shown) that supplies power for the various components of the wireless device 600. The power management system 620 can further include one or more processors or controllers that can control the transmission of signals, for example. In one embodiment, the baseband sub-system 630 is connected to a user interface 640 to facilitate various input and output of voice and/or data provided to and received from the user. The baseband sub-system 630 can also be connected to memory 650 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 300 GHz, such as in a range from about 450 MHz to 6 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A radio frequency filter comprising:
a plurality of series bulk acoustic wave resonators; and
a plurality of shunt bulk acoustic wave resonators, the plurality of series bulk acoustic wave resonators and the plurality of shunt bulk acoustic wave resonators configured and arranged to generate acoustic waves at both fundamental tones and second overtones and to suppress signals associated with the acoustic waves at the fundamental tones, a passband of the radio frequency filter with a lowest insertion loss defined by the acoustic waves generated at the second overtones of the plurality of series bulk acoustic wave resonators and the plurality of shunt bulk acoustic wave resonators.

2. The radio frequency filter of claim 1 wherein resonant frequencies of the fundamental tone of the plurality of series bulk acoustic wave resonators are aligned in frequency with resonant frequencies of the fundamental tone of the plurality of shunt bulk acoustic wave resonators.

3. The radio frequency filter of claim 1 wherein resonant frequencies of the second overtones of the plurality of series bulk acoustic wave resonators are aligned in frequency with antiresonant frequencies of the second overtones of the plurality of shunt bulk acoustic wave resonators.

4. The radio frequency filter of claim 1 wherein the plurality of series bulk acoustic wave resonators and the plurality of shunt bulk acoustic wave resonators each include piezoelectric material layers and dielectric layers disposed on top of the piezoelectric material layers and having thicknesses sufficient to cause the second overtones to be excited.

5. The radio frequency filter of claim 1 wherein the plurality of series bulk acoustic wave resonators and the plurality of shunt bulk acoustic wave resonators each include piezoelectric material layers and dielectric layers disposed on top of the piezoelectric material layers and having thicknesses sufficient to cause the second overtones to be excited with amplitudes at least as great as amplitudes of the fundamental tones.

6. The radio frequency filter of claim 1 wherein the plurality of series bulk acoustic wave resonators and the plurality of shunt bulk acoustic wave resonators are film bulk acoustic wave resonators.

7. The radio frequency filter of claim 1 wherein the plurality of series bulk acoustic wave resonators and the plurality of shunt bulk acoustic wave resonators are solidly mounted resonators.

8. The radio frequency filter of claim 1 configured as a ladder filter.

9. A radio frequency module including the radio frequency filter of claim 1.

10. A radio frequency device including the radio frequency module of claim 9.

11. A method of forming a radio frequency ladder filter having a passband, the method comprising:
forming a ladder filter including a plurality of series resonators coupled between an input and an output and a plurality of shunt resonators electrically connected between nodes between adjacent ones of the plurality of series resonators and ground; and
selecting thickness of a piezoelectric material layer, top electrode, and bottom electrode of series resonators of the filter to center a second overtone resonant frequency of each of the plurality of series resonators at an upper end of the passband.

12. The method of claim 11 further comprising determining a second overtone resonance frequency of shunt resonators of the filter to give a desired passband width for the filter.

13. The method of claim 12 further comprising calculating a spacing between the second overtone resonance frequencies of the series and shunt resonators.

14. The method of claim 13 further comprising calculating values for ΔT_{MTE} and ΔT_{SV} that would achieve the spacing between the second overtone resonance frequencies of the series and shunt resonators and a difference in resonance frequencies of the series and shunt resonators at fundamental tones of the series and shunt resonators of about 0 MHz.

15. The method of claim 14 wherein forming the ladder filter includes forming the series and shunt resonators with the selected thicknesses of the piezoelectric material layer, top electrode, and bottom electrode and the calculated values for ΔT_{MTE} and ΔT_{SV}.

16. The method of claim 14 wherein the values for ΔT_{MTE} and ΔT_{SV} are calculated from the formula
$$Δ {f}_{s} = \frac{Δ {f}_{s}}{Δ {T}_{MTE}} \times Δ {T}_{MTE} + \frac{Δ {f}_{s}}{Δ {T}_{SV}} \times Δ {T}_{SV} .$$

17. The method of claim 11 wherein the series and shunt resonators are formed as film bulk acoustic wave resonators.

18. The method of claim 11 wherein the series and shunt resonators are formed as solidly mounted resonators.

19. The method of claim 11 further comprising incorporating the radio frequency ladder filter into a radio frequency module.

20. The method of claim 19 further comprising incorporating the radio frequency module into a radio frequency device.
